(19) United States
(12) Patent Application Publication
(10) Pub. No.: US 2018/0371191 A1
(43) Pub. Date: Dec. 27, 2018

(54) BASE FILM FOR PRINTED CIRCUIT BOARD, SUBSTRATE FOR PRINTED CIRCUIT BOARD, AND METHOD FOR MANUFACTURING SUBSTRATE FOR PRINTED CIRCUIT BOARD

(71) Applicants: SUMITOMO ELECTRIC INDUSTRIES, LTD., Osaka-shi, Osaka (JP); SUMITOMO ELECTRIC PRINTED CIRCUITS, INC., Koka-shi, Shiga (JP)

(72) Inventors: Kayo HASHIZUME, Osaka-shi, Osaka (JP); Yoshio OKA, Osaka-shi, Osaka (JP); Takashi KASUGA, Osaka-shi, Osaka (JP); Kentaro OKAMOTO, Osaka-shi, Osaka (JP); Atsushi KIMURA, Koka-shi, Shiga (JP); Hiroshi UEDA, Koka-shi, Shiga (JP)

(73) Assignees: SUMITOMO ELECTRIC INDUSTRIES, LTD., Osaka-shi, Osaka (JP); SUMITOMO ELECTRIC PRINTED CIRCUITS, INC., Koka-shi, Shiga (JP)

(21) Appl. No.: 15/777,771

(22) PCT Filed: Nov. 22, 2016
(86) PCT No.: PCT/JP2016/084644

§ 371 Date: May 21, 2018

(30) Foreign Application Priority Data
Nov. 26, 2015 (JP) 2015-230743

(51) Int. Cl. C08J 5/18; H05K 1/03; H05K 3/12

(52) U.S. Cl. CPC C08J 5/18; H05K 1/0346; H05K 3/1208; H05K 3/1283; C08J 2379/08; G01N 21/3563; H05K 2203/161; H05K 2201/0129; H05K 2203/1131; H05K 2203/072; H05K 2203/0723; H05K 2201/0154

(57) ABSTRACT

A base film for a printed circuit board according to an embodiment of the present invention is a base film for a printed circuit board, the base film containing a polyimide as a main component. A ratio of a peak intensity around a wave number of 1705 cm⁻¹ to a peak intensity around a wave number of 1494 cm⁻¹ in an absorption intensity spectrum of a surface of the base film, the spectrum being measured at an angle of incidence of 45° by total reflection infrared absorption spectroscopy, is 0.50 or more and 1.10 or less. A substrate for a printed circuit board according to an embodiment of the present invention includes the base film for a printed circuit board and a metal layer stacked on the surface of the base film for a printed circuit board.

### TECHNICAL FIELD

The present invention relates to a base film for a printed circuit board, a substrate for a printed circuit board, and a method for manufacturing a substrate for a printed circuit board.

The present application claims priority from Japanese Patent Application No. 2015-230743 filed on Nov. 26, 2015, and the entire contents of the Japanese patent application are incorporated herein by reference.

### BACKGROUND ART

A widely used substrate for a printed circuit board includes an insulating base film formed of, for example, a resin and a metal layer that is formed of, for example, a metal and that is disposed on a surface of the base film, the substrate being used for obtaining a printed circuit board by etching the metal layer to form a conductive pattern.

A substrate for a printed circuit board, the substrate having a high peel strength between a base film and a metal layer, has been desired so that the metal layer is not peeled off from the base film when a bending stress is applied to a printed circuit board formed by using such a substrate for a printed circuit board.

Furthermore, in recent years, with the realization of electronic devices having a smaller size and higher performance, there has been a need for a higher density of printed circuit boards. With the miniaturization of a conductive pattern of a printed circuit board having a higher density, the conductive pattern easily peels off from a base film. Therefore, as a substrate for a printed circuit board, the substrate satisfying such a need for a higher density, there has been a need for a substrate for a printed circuit board, on which a fine conductive pattern can be formed and which has good adhesiveness between a metal layer and a base film.

To meet such a need, a technique is known in which a copper thin-film layer is formed on a surface of a base film by using, for example, a sputtering method and a copper thick-film layer is formed thereon by an electroplating method, to thereby increase the adhesiveness between the metal layer and the base film. However, it is known that, in the case where a metal layer is formed directly on a base film, main metal atoms of the metal layer diffuse into the base film with time, thereby decreasing the adhesiveness between the metal layer and the base film.

In view of the above, a technique has been proposed in which a chromium thin film is deposited by sputtering on a bonding surface of a copper Foil, the bonding surface facing a base film, and the resulting copper foil is thermocompression-bonded to the base film (refer to Japanese Unexamined Patent Application Publication No. 2000-340911). Such a metal thin film disposed at an interface between a metal layer and a base film, the metal thin film being made of a metal that is different from a main metal of the metal layer, inhibits migration of the main metal of the metal layer into the base film, thus achieving an advantage of suppressing a decrease in the adhesiveness between the metal layer and the base film, the decrease being caused by diffusion of main metal atoms of the metal layer into the base film.

### CITATION LIST

### Patent Literature

PTL 1: Japanese Unexamined Patent Application Publication No. 2000-340911

### SUMMARY OF INVENTION

A base film for a printed circuit board according to an embodiment of the present invention is a base film for a printed circuit board, the base film containing a polyimide as a main component. A ratio of a peak intensity around a wave number of 1705 cm⁻¹ to a peak intensity around a wave number of 1494 cm⁻¹ in an absorption intensity spectrum of a surface of the base film, the spectrum being measured at an angle of incidence of 45° by total reflection infrared absorption spectroscopy, is 0.50 or more and 1.10 or less.

A method for manufacturing a substrate for a printed circuit board according to another embodiment of the present invention is a method for manufacturing a substrate for a printed circuit board, the substrate including a base film containing a polyimide as a main component and a metal layer stacked on the base film. The method includes a step of subjecting a surface of the base film to an alkali treatment, a step of measuring an absorption intensity spectrum of the surface of the base film after the alkali treatment step at an angle of incidence of 45° by total reflection infrared absorption spectroscopy, a step of discriminating a base film that has, within a predetermined range, a ratio of a peak intensity around a wave number of 1705 cm⁻¹ or a peak intensity around a wave number of 1597 cm⁻¹ to another peak intensity in the absorption intensity spectrum obtained in the measurement step, and a step of stacking a metal layer on the surface of the base film discriminated in the discrimination step.

### BRIEF DESCRIPTION OF DRAWINGS

FIG. 1 is a schematic sectional view illustrating a substrate for a printed circuit board according to an embodiment of the present invention.

FIG. 2 is a detailed schematic sectional view illustrating the substrate for a printed circuit board in FIG. 1.

FIG. 3 is a flowchart illustrating a procedure of a method for manufacturing the substrate for a printed circuit board in FIG. 2.

FIG. 4 is a graph showing absorption intensity spectra of prototypes of a substrate for a printed circuit board as measured by total reflection infrared absorption spectroscopy.

### DESCRIPTION OF EMBODIMENTS

### [Technical Problem]

The above technique of forming a chromium thin film on a surface of a copper foil by using a sputtering method requires vacuum equipment, resulting in an increase in the costs of, for example, installation, maintenance, and operation of the equipment. In addition, an increase in the size of a substrate is limited in terms of equipment.

The present invention has been made in view of the circumstances described above. An object of the present invention is to provide a base film for a printed circuit board and a substrate for a printed circuit board, the base film and the substrate being relatively inexpensive and having good adhesiveness between a base film and a metal layer, and a method for manufacturing the substrate for a printed circuit board.

### [Advantageous Effects of the Present Disclosure]

A base film for a printed circuit board and a substrate for a printed circuit board according to embodiments of the present invention are relatively inexpensive and have good adhesiveness between a base film and a metal layer. A method for manufacturing a substrate for a printed circuit board according to an embodiment of the present invention can provide a substrate for a printed circuit board, the substrate being relatively inexpensive and having good adhesiveness between a base film and a metal layer.

### [Description of Embodiment of the Present Invention]

A base film for a printed circuit board according to an embodiment of the present invention is a base film for a printed circuit board, the base film containing a polyimide as a main component. A ratio of a peak intensity around a wave number of 1705 cm⁻¹ to a peak intensity around a wave number of 1494 cm⁻¹ in an absorption intensity spectrum of a surface of the base film, the spectrum being measured at an angle of incidence of 45° by total reflection infrared absorption spectroscopy, is 0.50 or more and 1.10 or less.

In the absorption intensity spectrum of a surface of the base film as measured by total reflection infrared absorption spectroscopy, the peak around a wave number of 1705 cm⁻¹ is attributable to a carbonyl group of an imide bond of the polyimide, and the peak around a wave number of 1494 cm⁻¹ is attributable to a benzene ring between imide bonds. Accordingly, in the base film for a printed circuit board, the ratio of the peak intensity around a wave number of 1705 cm⁻¹ to the peak intensity around a wave number of 1494 cm⁻¹ in the total reflection infrared absorption spectroscopy is within the above range, that is, a ratio of the number of carbonyl groups of imide bonds to the number of benzene rings between imide bonds of the polyimide is within a certain range. That is, since the base film for a printed circuit board has a ring-opening ratio of imide rings within a certain range, metal atoms of a metal layer are relatively easily bonded to portions where imide rings are opened, and a decrease in the strength due to opening of imide rings is relatively small. Accordingly, when a metal layer is stacked on the base film for a printed circuit board, the peel strength of the metal layer is relatively high, and good adhesion strength between the metal layer and the base film is achieved. The term “main component” refers to a component having the highest content and refers to a component contained in an amount of, for example, 50% by mass or more. The term “total reflection infrared absorption spectroscopy” refers to a measurement method using a single-reflection attenuated total reflection (ATR) measuring apparatus equipped with a diamond prism. The term “peak intensity” around each wave number in an absorption intensity spectrum means a maximum value around the wave number and preferably means a peak intensity within plus or minus 8 cm⁻¹ from the wave number, though it depends on the measurement error of the measuring apparatus.

A substrate for a printed circuit board according to another embodiment of the present invention is a substrate for a printed circuit board, the substrate including the above base film for a printed circuit board and a metal layer stacked on the surface of the base film for a printed circuit board.

Since the substrate for a printed circuit board includes the base film for a printed circuit board and a metal layer stacked on the base film, the base film having good adhesion strength between the metal layer and the base film, the substrate has high adhesion strength of the metal layer and high strength of a conductive pattern formed by patterning the metal layer and thus can provide a highly reliable printed circuit board.

The metal layer preferably includes a sintered layer of metal particles. Such a metal layer including a sintered layer of metal particles can be formed at a relatively low cost.

A method for manufacturing a substrate for a printed circuit board according to still another embodiment of the present invention is a method for manufacturing a substrate for a printed circuit board, the substrate including a base film containing a polyimide as a main component and a metal layer stacked on the base film. The method includes a step of subjecting a surface of the base film to an alkali treatment, a step of measuring an absorption intensity spectrum of the surface of the base film after the alkali treatment step at an angle of incidence of 45° by total reflection infrared absorption spectroscopy, a step of discriminating a base film that has, within a predetermined range, a ratio of a peak intensity around a wave number of 1705 cm⁻¹ or a peak intensity around a wave number of 1597 cm⁻¹ to another peak intensity in the absorption intensity spectrum obtained in the measurement step, and a step of stacking a metal layer on the surface of the base film discriminated in the discrimination step.

In the absorption intensity spectrum of a surface of the base film measured by total reflection infrared absorption spectroscopy, the peak around a wave number of 1705 cm⁻¹ is attributable to a carbonyl group of an imide bond, and the peak around a wave number of 1597 cm⁻¹ is attributable to a carbonyl group in a portion where an imide ring is opened (for example, COOH or COONa formed by opening of an imide ring). Accordingly, in the method for manufacturing a substrate for a printed circuit board, the method including the discrimination step of discriminating whether the base film is good or not on the basis of the ratio of the peak intensity around a wave number of 1705 cm⁻¹ or the peak intensity around a wave number of 1597 cm⁻¹ to another peak intensity in the absorption intensity spectrum, only a base film having a ring-opening ratio of imide rings within a certain range can be used. Therefore, a substrate for a printed circuit board, the substrate being obtained by the method for manufacturing a substrate for a printed circuit board, has relatively high adhesiveness (peel strength) between the base film and the metal layer.

The discrimination step preferably includes discriminating a base film that has a ratio of the peak intensity around a wave number of 1705 cm⁻¹ to a peak intensity around a wave number of 1494 cm⁻¹ of 0.50 or more and 1.10 or less. In an absorption intensity spectrum of a polyimide measured by total reflection infrared absorption spectroscopy, the peak around a wave number of 1494 cm⁻¹ and the peak around a wave number of 1705 cm⁻¹ are relatively easily discriminated. Accordingly, in the discrimination step, by discriminating a base film that has, within the above range, the ratio of the peak intensity around a wave number of 1705 cm⁻¹ to the peak intensity around a wave number of 1494 cm⁻¹, a base film having a ring-opening ratio of imide rings within a certain range can be more reliably discriminated. As a result, a substrate for a printed circuit board, the substrate having relatively high adhesiveness of the metal layer, can be more reliably obtained by using the base film in which metal atoms of the metal layer are relatively easily bonded to portions where imide rings are opened and whose strength is relatively unlikely to decrease.

The stacking step preferably includes a step of applying a metal particle dispersion liquid to the surface of the base film and heating the metal particle dispersion liquid. When the stacking step includes a step of forming a sintered layer of metal particles by application of a metal particle dispersion liquid to the surface of the base film, and heating of the metal particle dispersion liquid, the metal layer can be relatively easily stacked on the surface of the base film at a low cost without the need for a large apparatus such as vacuum equipment.

### [Details of Embodiments of the Present Invention]

A base film for a printed circuit board, a substrate for a printed circuit board, and a method for manufacturing a substrate for a printed circuit board according to embodiments of the present invention will now be described in detail with reference to the drawings.

### [Base Film for Printed Circuit Board]

A base film for a printed circuit board according to an embodiment of the present invention is a base film for a printed circuit board, the base film containing a polyimide as a main component. A surface of the base film for a printed circuit board is modified, and some of imide rings of the polyimide are opened. This modification can be performed by a treatment method such an alkaline treatment or a plasma treatment.

### (Polyimide)

The polyimide that can be used as the main component of the base film for a printed circuit board may be a thermosetting polyimide (also referred to as a condensation-type polyimide) or a thermoplastic polyimide. Of these, a thermosetting polyimide is preferred from the viewpoint of, for example, heat resistance, tensile strength, and modulus of elasticity in tension.

The polyimide may be a homopolymer having a single structural unit, a copolymer having two or more structural units, or a polymer obtained by blending two or more homopolymers. A polyimide having a structural unit represented by formula (1) below is preferred.

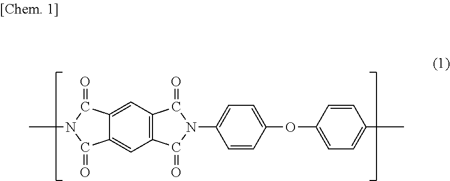

The structural unit represented by formula (1) above can be obtained by, for example, synthesizing a polyamic acid, which is a polyimide precursor, by using pyromellitic dianhydride and 4,4′-diaminodiphenyl ether, and imidizing the polyamic acid by heating or the like.

The lower limit of the content of the structural unit is preferably 10% by mass, more preferably 15% by mass, and still more preferably 18% by mass. The upper limit of the content of the structural unit is preferably 50% by mass, more preferably 40% by mass, and still more preferably 35% by mass. When the content of the structural unit is less than the lower limit, the base film for a printed circuit board may have insufficient strength. In contrast, when the content of the structural unit exceeds the upper limit, the base film for a printed circuit board may have insufficient flexibility.

### (Total Reflection Infrared Absorption Spectroscopy)

The lower limit of a ratio of the peak intensity around a wave number of 1705 cm⁻¹ to the peak intensity around a wave number of 1494 cm⁻¹ in an absorption intensity spectrum of the surface of the base film for a printed circuit board, the spectrum being measured at an angle of incidence of 45° by total reflection infrared absorption spectroscopy, is 0.50, preferably 0.60, and more preferably 0.70. The upper limit of the ratio of the peak intensity around a wave number of 1705 cm⁻¹ to the peak intensity around a wave number of 1494 cm⁻¹ in the absorption intensity spectrum is 1.10, preferably 1.05, and more preferably 1.00. When the ratio of the peak intensity around a wave number of 1705 cm⁻¹ to the peak intensity around a wave number of 1494 cm⁻¹ in the absorption intensity spectrum is less than the lower limit, the ring-opening ratio of imide rings is excessively high, and the base film may have insufficient strength. In contrast, when the ratio of the peak intensity around a wave number of 1705 cm⁻¹ to the peak intensity around a wave number of 1494 cm⁻¹ in the absorption intensity spectrum exceeds the upper limit, the ring-opening ratio of imide rings is low, and the adhesion strength of a metal layer may not be sufficiently improved.

The ratio of the peak intensity around a wave number of 1705 cm⁻¹ to the peak intensity around a wave number of 1494 cm⁻¹ in the absorption intensity spectrum will be described in detail. The peak intensity around a wave number of 1494 cm⁻¹ in the absorption intensity spectrum is a peak intensity that represents the number of benzene rings and is a value that does not change even when imide rings of the polyimide are opened. On the other hand, the peak intensity around a wave number of 1705 cm⁻¹ in the absorption intensity spectrum corresponds to the stretching vibration of a carbonyl group of an imide bond, is a peak intensity that represents the number of carbonyl groups of imide bonds, and is a value that decreases when imide rings of the polyimide are opened. Accordingly, the ratio of the peak intensity around a wave number of 1705 cm⁻¹ to the peak intensity around a wave number of 1494 cm⁻¹ in the absorption intensity spectrum can be used as an index that represents the ring-opening ratio of imide rings of the polyimide.

In the base film for a printed circuit board, since the ratio of the peak intensity around a wave number of 1705 cm⁻¹ to the peak intensity around a wave number of 1494 cm⁻¹ in the absorption intensity spectrum is within the above range, metal atoms of a metal layer are relatively easily bonded to portions where imide rings are opened, and a decrease in strength is relatively small. Accordingly, when a metal layer is stacked on the base film for a printed circuit board, the peel strength of the metal layer is relatively high, and good adhesion strength between the metal layer and the base film is achieved.

In the absorption intensity spectrum measured at an angle of incidence of 45° by total reflection infrared absorption spectroscopy, a carbonyl group in a portion where an imide ring is opened forms a peak around a wave number of 1597 cm⁻¹ as a result of a change in the period of the vibration thereof. Ring-opening of imide rings in the base film for a printed circuit board is conducted by, for example, an alkali treatment using an aqueous solution of sodium hydroxide. In this case, in a portion where an imide ring is opened by using the aqueous solution of sodium hydroxide, COOH (carboxy group) in which hydrogen is bonded to one of carbonyl groups or COONa in which sodium is bonded to one of carbonyl groups is generated. Note that the wave number of the peak formed by a carbonyl group in a portion where an imide ring is opened is substantially the same regardless of the type of atom bonded to the end of the carbonyl group.

Accordingly, in a base film subjected to an alkali treatment with an aqueous solution of sodium hydroxide, a ratio of the peak intensity around a wave number of 1597 cm⁻¹ due to a carbonyl group in a portion where an imide ring is opened to the peak intensity around a wave number of 1705 cm⁻¹ due to a carbonyl group of an imide bond in the absorption intensity spectrum can also be used as an index that represents the ring-opening ratio of imide rings of the polyimide. The lower limit of the ratio of the peak intensity around a wave number of 1597 cm⁻¹ to the peak intensity around a wave number of 1705 cm⁻¹ in the absorption intensity spectrum is preferably 0.40 and more preferably 0.45. The upper limit of the ratio of the peak intensity around a wave number of 1597 cm⁻¹ to the peak intensity around a wave number of 1705 cm⁻¹ in the absorption intensity spectrum is preferably 0.90 and more preferably 0.70. When the ratio of the peak intensity around a wave number of 1597 cm⁻¹ to the peak intensity around a wave number of 1705 cm⁻¹ in the absorption intensity spectrum is less than the lower limit, the ring-opening ratio of imide rings is low, and thus the adhesion strength of a metal layer may not be sufficiently improved. In contrast, when the ratio of the peak intensity around a wave number of 1597 cm⁻¹ to the peak intensity around a wave number of 1705 cm⁻¹ in the absorption intensity spectrum exceeds the upper limit, the ring-opening ratio of imide rings is excessively high, and the base film may have insufficient strength.

The lower limit of a ratio of the peak intensity around a wave number of 1597 cm⁻¹ to the peak intensity around a wave number of 1494 cm⁻¹ in the absorption intensity spectrum is preferably 0.40 and more preferably 0.45. The upper limit of the ratio of the peak intensity around a wave number of 1597 cm⁻¹ to the peak intensity around a wave number of 1494 cm⁻¹ in the absorption intensity spectrum is preferably 0.60 and more preferably 0.50. When the ratio of the peak intensity around a wave number of 1597 cm⁻¹, to the peak intensity around a wave number of 1494 cm⁻¹ in the absorption intensity spectrum is less than the lower limit, the ring-opening ratio of imide rings is low, and the adhesion strength of a metal layer may not be sufficiently improved. In contrast, when the ratio of the peak intensity around a wave number of 1597 cm⁻¹ to the peak intensity around a wave number of 1494 cm⁻¹ in the absorption intensity spectrum exceeds the upper limit, the ring-opening ratio of imide rings is excessively high, and the base film may have insufficient strength.

### <Advantage>

According to the base film for a printed circuit board, since the ratio of the peak intensity around a wave number of 1705 cm⁻¹ to the peak intensity around a wave number of 1494 cm⁻¹ in the absorption intensity spectrum is within the above range, the ring-opening ratio of imide rings of the polyimide is within a preferred range. Therefore, when a metal layer is stacked on the base film for a printed circuit board, the peel strength of the metal layer is relatively high, and good adhesion strength between the metal layer and the base film is achieved.

### [Substrate for Printed Circuit Board]

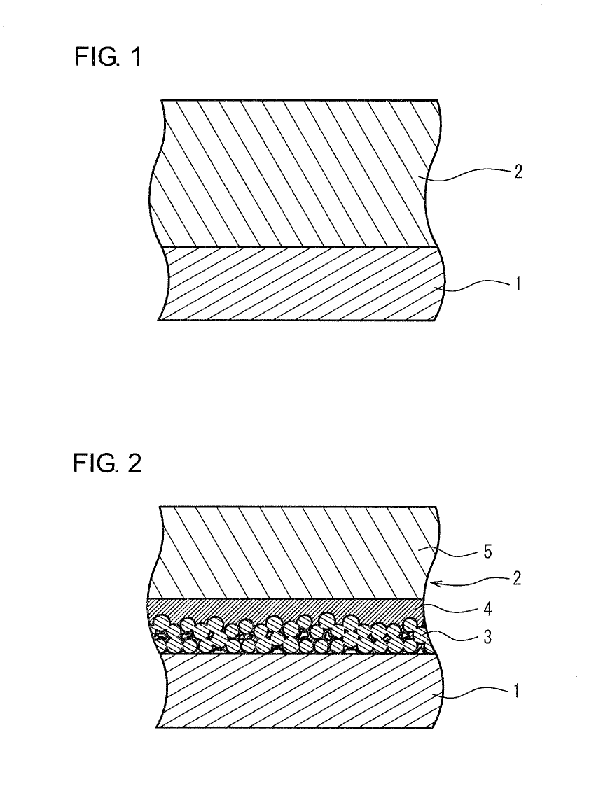

As illustrated in FIG. 1, a substrate for a printed circuit board according to an embodiment of the present invention includes the above-described base film 1 for a printed circuit board and a metal layer 2 stacked on a surface (modified surface) of the base film 1 for a printed circuit board.

As described above, since imide rings on a polyimide surface on which the metal layer 2 is to be stacked are opened in a particular ratio range, the substrate for a printed circuit board has relatively high adhesiveness (peel strength) between the base film 1 and the metal layer 2.

### <Base Film>

The base film 1 has the structure described above. Total reflection infrared absorption spectroscopy of the base film 1 of the substrate for a printed circuit board can be performed after the metal layer 2 is removed by etching with an acidic solution.

### (Etching Method)

The acidic solution used in etching for removing the metal layer 2 may be an acidic etchant that is usually used for removing a conductive layer. Examples thereof include a copper chloride solution, hydrochloric acid, sulfuric acid, and aqua regia.

The lower limit of the temperature of the etchant during etching is preferably 10° C. and more preferably 20° C. The upper limit of the temperature of the etchant is preferably 90° C. and more preferably 70° C. When the temperature of the etchant is less than the lower limit, the time necessary for etching is long, and workability may decrease. In contrast, when the temperature of the etchant exceeds the upper limit, the energy cost for temperature control may be unnecessarily increased.

The lower limit of the etching time is preferably 1 minute and more preferably 10 minutes. The upper limit of the etching time is preferably 60 minutes and more preferably 30 minutes. When the etching time is less than the lower limit, the etchant has a high concentration, and it may become difficult to handle the etchant. In contrast, when the etching time exceeds the upper limit, workability may decrease.

### <Metal Layer>

In the substrate for a printed circuit board, the metal layer 2 may include a sintered layer of metal particles. The sintered layer of metal particles can be relatively easily formed at a low cost without the need for a large apparatus such as vacuum equipment. Thus, the manufacturing cost of the substrate for a printed circuit board can be reduced by providing the sintered layer of metal particles.

Specifically, for example, as illustrated in FIG. 2, a metal layer 2 may have a structure including a sintered layer 3 stacked on a surface of a base film 1 by sintering a plurality of metal particles, an electroless plating layer 4 stacked on a surface of the sintered layer 3 by electroless plating, and an electroplating layer 5 further stacked on a surface of the electroless plating layer 4 by electroplating.

For example, copper (Cu), nickel (Ni), aluminum (Al), gold (Au), or silver (Ag) can be used as the main metal of the metal layer 2. Of these, copper is suitably used as a metal that has good electrical conductivity, has good adhesiveness to the base film 1, is easily patterned by etching, and is relatively inexpensive. Furthermore, in the case where the main metal of the metal layer 2 is copper, the effect of suppressing a decrease in the adhesion strength, the decrease being due to opening of imide rings of the polyimide of the base film 1, becomes significant.

### (Sintered Layer)

The sintered layer 3 can be stacked on a surface of the base film 1 by applying, to the modified surface of the base film 1, a metal particle dispersion liquid (ink) containing a plurality of metal particles that contain, as a main component, a metal serving as the main metal of the metal layer 2, and firing the metal particle dispersion liquid. Use of a metal particle dispersion liquid enables the metal layer 2 to be easily formed on the surface of the base film 1 at a low cost.

The lower limit of the mean particle size of the metal particles that form the sintered layer 3 is preferably 1 nm and more preferably 30 nm. The upper limit of the mean particle size of the metal particles is preferably 500 nm and more preferably 100 nm. When the mean particle size of the metal particles is less than the lower limit, for example, dispersibility and stability of the metal particles in the metal particle dispersion liquid decrease, and consequently, the metal particles may not be easily uniformly stacked on the surface of the base film 1. In contrast, when the mean particle size of the metal particles exceeds the upper limit, gaps between the metal particles are large, and it may not be easy to reduce the porosity of the sintered layer 3. The term “mean particle size” refers to a particle size at which a cumulative volume value becomes 50% in a particle size distribution measured by a laser diffraction method.

The lower limit of the average thickness of the sintered layer 3 is preferably 50 nm and more preferably 100 nm. The upper limit of the average thickness of the sintered layer 3 is preferably 2 μm and more preferably 1.5 μm. When the average thickness of the sintered layer 3 is less than the lower limit, portions where metal particles are not present in plan view increase, which may result in a decrease in the electrical conductivity. In contrast, when the average thickness of the sintered layer 3 exceeds the upper limit, it may become difficult to sufficiently reduce the porosity of the sintered layer 3 or the metal layer 2 may have an unnecessarily large thickness.

### (Electroless Plating Layer)

The electroless plating layer 4 is formed by stacking the same metal as the main metal of the metal particles that form the sintered layer 3 by subjecting the outer surface of the sintered layer 3 to electroless plating. The electroless plating layer 4 is formed so as to be impregnated inside the sintered layer 3. Specifically, gaps between the metal particles that form the sintered layer 3 are filled with the main metal by electroless plating, thereby decreasing the gaps inside the sintered layer 3. By filling the gaps between the metal particles with the electroless plating metal to decrease the gaps between the metal particles, it is possible to suppress peeling off of the sintered layer 3 from the base film 1, the peeling-off starting from breaking in the gaps.

In some cases, the electroless plating layer 4 is formed only inside the sintered layer 3 depending on the conditions for electroless plating. In general, the lower limit of the average thickness of the electroless plating layer 4 formed on the outer surface of the sintered layer 3 (the average thickness that does not include the thickness of plated metal inside the sintered layer 3) is preferably 0.2 μm and more preferably 0.3 μm. The upper limit of the average thickness of the electroless plating layer 4 formed on the outer surface of the sintered layer 3 is preferably 1 μm and more preferably 0.7 μm. When the average thickness of the electroless plating layer 4 formed on the outer surface of the sintered layer 3 is less than the lower limit, the gaps between the metal particles of the sintered layer 3 are not sufficiently filled with the electroless plating layer 4, and the porosity cannot be sufficiently reduced. Thus, the peel strength between the base film 1 and the metal layer 2 may become insufficient. In contrast, when the average thickness of the electroless plating layer 4 formed on the outer surface of the sintered layer 3 exceeds the upper limit, the time necessary for electroless plating becomes long, and the manufacturing cost may increase.

### (Electroplating Layer)

The electroplating layer 5 is formed by further stacking the main metal, by electroplating, on the outer surface side of the sintered layer 3, that is, on the outer surface of the electroless plating layer 4. This electroplating layer 5 enables the thickness of the metal layer 2 to be adjusted easily and accurately. In addition, use of electroplating enables the thickness of the metal layer 2 to be increased in a short time.

The thickness of the electroplating layer 5 is determined in accordance with the type and the thickness of conductive pattern necessary for a printed circuit board formed by using the substrate for a printed circuit board and is not particularly limited. In general, the lower limit of the average thickness of the electroplating layer 5 is preferably 1 μm and more preferably 2 μm. The upper limit of the average thickness of the electroplating layer 5 is preferably 100 μm and more preferably 50 μm. When the average thickness of the electroplating layer 5 is less than the lower limit, the metal layer 2 may be easily damaged. In contrast, when the average thickness of the electroplating layer 5 exceeds the upper limit, the substrate for a printed circuit board may have an unnecessarily large thickness or the substrate for a printed circuit board may have insufficient flexibility.

### <Advantage>

As described above, the substrate for a printed circuit board includes the base film 1 in which imide rings of the polyimide are opened in a particular ratio range and thus has relatively high adhesiveness (peel strength) between the base film 1 and the metal layer 2. Accordingly, a printed circuit board formed by patterning the metal layer 2 of the substrate for a printed circuit board has a relatively high peel strength of a conductive pattern and thus has relatively high reliability.

### [Method for Manufacturing Substrate for Printed Circuit Board]

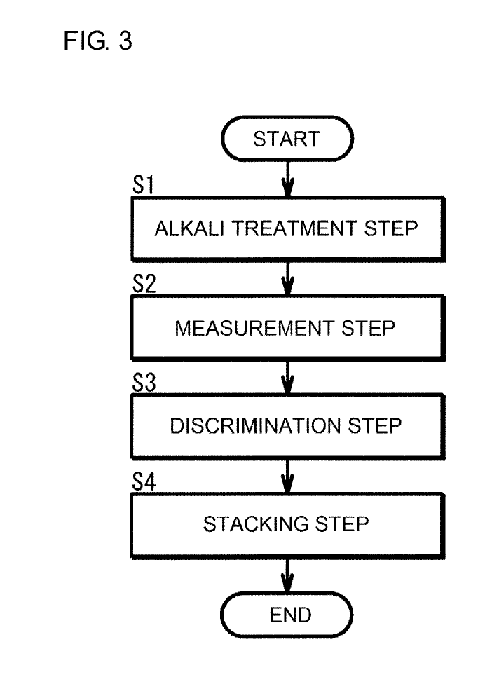

As illustrated in FIG. 3, the substrate for a printed circuit board can be manufactured by, as a specific example, a method including a step of subjecting a surface of a base film 1 that contains a polyimide as a main component to an alkali treatment (step S1: alkali treatment step); a step of measuring an absorption intensity spectrum of the surface (the surface subjected to the alkali treatment) of the base film 1 after the alkali treatment step by total reflection infrared absorption spectroscopy (step S2: measurement step); a step of discriminating a base film that has, within a predetermined range, a ratio of a peak intensity around a wave number of 1705 cm⁻¹ or a peak intensity around a wave number of 1597 cm⁻¹ to another peak intensity in the absorption intensity spectrum obtained in the measurement step (step S3: discrimination step); and a step of stacking a metal layer on the surface (the surface subjected to the alkali treatment) of the base film 1 discriminated in the discrimination step (step S4: stacking step).

### <Alkali Treatment Step>

In the alkali treatment step of step SI, an alkali liquid is brought into contact with a surface of a base film 1 on which a metal layer 2 is to be stacked, to thereby open some of imide rings of a polyimide which is a main component of the base film 1.

Examples of the alkaline liquid used in this alkali treatment step include aqueous solutions of sodium hydroxide, potassium hydroxide, ammonia, calcium hydroxide, tetramethylammonium hydroxide, lithium hydroxide, monoethanolamine, and the like; and aqueous solutions of any of these and hydrogen peroxide. Of these, an aqueous solution of sodium hydroxide is preferably used.

The pH of the alkaline liquid used in the alkali treatment step may be, for example, 12 or more and 15 or less. The time during which the base film 1 is brought into contact with the alkali liquid may be, for example, 15 seconds or more and 10 minutes or less. The temperature of the alkali liquid may be, for example, 10° C. or higher and 70° C. or lower.

The alkali treatment step preferably includes a water-washing step of washing the base film 1 with water. In this water-washing step, the base film 1 is washed with water to remove the alkali liquid adhering to the surface of the base film 1. The alkali treatment step more preferably includes a drying step of drying washing water in the water-washing step. By evaporating water in the base film 1, ions in the base film 1 are deposited as a metal or a metal oxide or bonded to a resin component or the like of the base film 1. Thus, the quality of the base film 1 can be stabilized.

### <Measurement Step>

In the measurement step of step S2, an infrared absorption intensity spectrum of the alkali-treated surface of the base film 1 is measured at an angle of incidence of 45° by total reflection infrared absorption spectroscopy by using a single-reflection attenuated total reflection (ATR) measuring apparatus equipped with a diamond prism. This measurement of the absorption intensity spectrum can be performed by sampling a part of the base film 1 that has been subjected to the alkali treatment.

### <Discrimination Step>

In the discrimination step of step S3, in the absorption intensity spectrum obtained in the measurement step, a ratio of the peak intensity around a wave number of 1705 cm⁻¹ due to a carbonyl group of an imide bond or the peak intensity around a wave number of 1597 cm⁻¹ due to a carbonyl group in a portion where an imide ring is opened (for example, COOH or COONa) to an intensity of another peak is calculated. A base film I in which the ratio is within a predetermined range is evaluated as a good product. A base film 1 in which the calculated ratio is outside the predetermined range is excluded.

The peak used for calculating the ratio to the intensity of the other peak is preferably a peak around a wave number of 1705 cm⁻¹, the peak being observed relatively clearly. The other peak is preferably a peak which has a relatively high peak intensity and whose value is not changed by an alkali treatment. A peak around a wave number of 1494 cm⁻¹, the peak corresponding to a benzene ring between imide bonds of the polyimide is particularly preferred. However, a peak whose value is changed by an alkali treatment in accordance with the opening of imide rings may be used as the other peak. As such a peak whose value is changed, a peak around a wave number of 1597 cm⁻¹ may be used relative to a wave number of 1705 cm⁻¹. Alternatively, a peak around a wave number of 1705 cm⁻¹ may be used relative to a wave number of 1597 cm⁻¹.

The ranges of the ratios of the peak intensities are as described in the base film for a printed circuit board.

### <Stacking Step>

In the stacking step of step S4, a metal layer is stacked on a surface of the base film 1 that is discriminated to have the ratio of peak intensities within the predetermined range in the discrimination step. This stacking step preferably includes a step of forming a sintered layer 3 by application and heating of a metal particle dispersion liquid containing a plurality of metal particles (sintered layer formation step) from the viewpoint that a metal layer can be formed at a relatively low cost. The stacking step preferably includes a step of forming an electroless plating layer 4 by electroless plating (electroless plating layer formation step) and a step of forming an electroplating layer 5 by electroplating (electroplating layer formation step).

### (Sintered Layer Formation Step)

The metal particle dispersion liquid used in the sintered layer formation step preferably contains a dispersion medium of metal particles and a dispersant for uniformly dispersing the metal particles in the dispersion medium. By using such a metal particle dispersion liquid in which metal particles are uniformly dispersed, the metal particles can be caused to uniformly adhere to a surface of the base film 1, and a uniform sintered layer 3 can be formed on the surface of the base film 1.

The metal particles contained in the metal particle dispersion liquid can be manufactured by a high-temperature treatment method, a liquid-phase reduction method, a gas-phase method, or the like. Metal particles manufactured by the liquid-phase reduction method, with which particles having a uniform particle size can be manufactured at a relatively low cost, are preferably used.

The dispersant contained in the metal particle dispersion liquid is not particularly limited. However, a polymeric dispersant having a molecular weight of 2,000 or more and 300,000 or less is preferably used. By using a polymeric dispersant having a molecular weight in the above range, metal particles can be satisfactorily dispersed in the dispersion medium, and the resulting sintered layer 3 has film properties of being dense and free from defects. When the molecular weight of the dispersant is less than the lower limit, the effect of preventing aggregation of metal particles to maintain the dispersion may be insufficiently provided. As a result, the sintered layer 3 that is dense and has few defects may not be stacked on the base film 1. In contrast, when the molecular weight of the dispersant exceeds the upper limit, the dispersant may be excessively bulky. As a result, during heating conducted after application of the metal particle dispersion liquid, sintering between metal particles may be inhibited, which may result in formation of voids. In addition, when the dispersant is excessively bulky, the sintered layer 3 may have decreased denseness in terms of film properties, or the decomposition residue of the dispersant may decrease the electrical conductivity.

The dispersant is preferably free from sulfur, phosphorus, boron, halogen elements, and alkali metals from the viewpoint of preventing deterioration of components. Examples of the preferred dispersant include amine-based polymeric dispersants such as polyethyleneimine and polyvinylpyrrolidone; hydrocarbon-based polymeric dispersants having a carboxylic acid group in the molecule thereof, such as polyacrylic acid and carboxymethyl cellulose; and polymeric dispersants having polar groups, such as Poval (polyvinyl alcohol), styrene-maleic acid copolymers, olefin-maleic acid copolymers, and copolymers having a polyethyleneimine moiety and a polyethylene oxide moiety in one molecule thereof, all of which have a molecular weight within the above-described range.

The dispersant may be dissolved in water or a water-soluble organic solvent, and the resulting solution may be added to the reaction system. The content of the dispersant is preferably 1 part by mass or more and 60 parts by mass or less relative to 100 parts by mass of the metal particles. The dispersant surrounds the metal particles to prevent aggregation and satisfactorily disperse the metal particles. However, when the content of the dispersant is less than the lower limit, this effect of preventing aggregation may be insufficiently provided. In contrast, when the content of the dispersant exceeds the upper limit, in the heating step after application of the metal particle dispersion liquid, the excessive dispersant inhibits sintering of the metal particles, which may result in formation of voids. In addition, the decomposition residue of the polymeric dispersant may remain as impurities in the sintered layer 3 and decrease the electrical conductivity.

The content of water serving as the dispersion medium in the metal particle dispersion liquid is preferably 20 parts by mass or more and 1900 parts by mass or less relative to 100 parts by mass of the metal particles. The water serving as the dispersion medium causes the dispersant to be sufficiently swelled to enable satisfactory dispersion of the metal particles surrounded by the dispersant. However, when the content of water is less than the lower limit, this effect of swelling the dispersant, the effect being exerted by water, may be insufficiently provided. In contrast, when the content of water exceeds the upper limit, the metal particle dispersion liquid has a low content of the metal particles, and a satisfactory sintered layer 3 having required thickness and density may not be formed on the surface of the base film 1.

As the organic solvent that is optionally added to the metal particle dispersion liquid, various water-soluble organic solvents can be used. Specific examples thereof include alcohols such as methyl alcohol, ethyl alcohol, n-propyl alcohol, isopropyl alcohol, n-butyl alcohol, isobutyl alcohol, sec-butyl alcohol, and tert-butyl alcohol; ketones such as acetone and methyl ethyl ketone; esters of a polyhydric alcohol such as ethylene glycol or glycerin or another compound; and glycol ethers such as ethylene glycol monoethyl ether and diethylene glycol monobutyl ether.

The content of the water-soluble organic solvent in the metal particle dispersion liquid is preferably 30 parts by mass or more and 900 parts by mass or less relative to 100 parts by mass of the metal particles. When the content of the water-soluble organic solvent is less than the lower limit, the effect of adjusting the vapor pressure and adjusting the viscosity of the dispersion liquid, the effect being exerted by the organic solvent, may be insufficiently provided. In contrast, when the content of the water-soluble organic solvent exceeds the upper limit, the effect of swelling the dispersant, the effect being exerted by water, may be insufficiently provided, which may result in occurrence of aggregation of the metal particles in the metal particle dispersion liquid.

Examples of the method for applying the metal particle dispersion liquid to the base film 1 include conventionally known coating methods such as spin coating, spray coating, bar coating, die coating, slit coating, roll coating, and dip coating. Alternatively, the metal particle dispersion liquid may be applied to only a portion of a surface of the base film 1 by screen-printing, by using a dispenser, or the like.

Subsequently, a coating film of the metal particle dispersion liquid formed by applying the metal particle dispersion liquid to the base film 1 is heated. As a result, the solvent and the dispersant of the metal particle dispersion liquid are evaporated or thermally decomposed, and the remaining metal particles are sintered to obtain a sintered layer 3 fixed to the surface of the base film 1. Before the heating, the coating film of the metal particle dispersion liquid is preferably dried.

The sintering is preferably performed in an atmosphere in which a certain amount of oxygen is contained. The lower limit of the oxygen concentration of the atmosphere during the sintering is preferably 1 ppm by volume and more preferably 10 ppm by volume. The upper limit of the oxygen concentration is preferably 10,000 ppm by volume and more preferably 1,000 ppm by volume. When the oxygen concentration is less than the lower limit, the amount of metal oxide generated in the vicinity of the interface of the sintered layer 3 is small, and the adhesion strength between the base film 1 and the sintered layer 3 may not be sufficiently improved. In contrast, when the oxygen concentration exceeds the upper limit, the metal particles are excessively oxidized, which may result in a decrease in the electrical conductivity of the sintered layer 3.

The lower limit of the sintering temperature is preferably 150° C. and more preferably 200° C. The upper limit of the sintering temperature is preferably 500° C. and more preferably 400° C. When the sintering temperature is lower than the lower limit, the metal particles cannot be connected together, and the sintered layer 3 may be disintegrated when an electroless plating layer 4 is subsequently formed. In contrast, when the sintering temperature exceeds the upper limit, the base film 1 may be deformed.

### (Electroless Plating Layer Formation Step)

In the electroless plating layer formation step, an outer surface of the sintered layer 3 that is stacked on the surface of the base film 1 in the sintered layer formation step is subjected to electroless plating to form an electroless plating layer 4.

The electroless plating is preferably performed together with processes such as a cleaner step, a water-washing step, an acid treatment step, a water-washing step, a pre-dip step, an activator step, a water-washing step, a reduction step, and a water-washing step.

After the electroless plating layer 4 is formed by electroless plating, heat treatment is preferably further performed. The heat treatment performed after the formation of the electroless plating layer 4 further increases the amount of, for example, a metal oxide near the interface of the sintered layer 3 with the base film 1 to further increase the adhesion strength between the base film 1 and the sintered layer 3. The temperature and the oxygen concentration in the heat treatment after electroless plating may be the same as the heating temperature and the oxygen concentration in the sintered layer formation step.

### (Electroplating Layer Formation Step)

In the electroplating layer formation step, an electroplating layer 5 is stacked on the outer surface of the electroless plating layer 4 by electroplating. In this electroplating layer formation step, the thickness of the whole metal layer 3 is increased to a desired thickness.

This electroplating can be performed with a conventionally known electroplating bath corresponding to the metal to be plated, such as copper, nickel, or silver, under conditions that are appropriately selected so that a metal layer 3 having a desired thickness is rapidly formed without defects.

### <Advantage>

Since the method for manufacturing a substrate for a printed circuit board includes the discrimination step of conducting total reflection infrared absorption spectroscopy of a surface of the base film 1 containing a polyimide as a main component, it is possible to obtain a base film 1 having, within a particular range, a ring-opening ratio of imide rings of the polyimide. Accordingly, a substrate for a printed circuit board, the substrate being obtained by the method for manufacturing a substrate for a printed circuit board, has relatively high adhesiveness (peel strength) between the base film 1 and the metal layer 2.

### Other Embodiments

It is to be understood that the embodiments disclosed herein are only illustrative and are not restrictive in all respects. The scope of the present invention is not limited to the configurations of the embodiments and is defined by the claims described below. The scope of the present invention is intended to cover all the modifications within the meaning and scope of the claims and their equivalents.

The substrate for a printed circuit board may be manufactured by a method different from the manufacturing method illustrated in FIG. 3. Specifically, in the substrate for a printed circuit board, a surface of the base film may be modified by, for example, a plasma treatment or the like instead of the alkali treatment.

Furthermore, details of the structure and the stacking method of the substrate for a printed circuit board are not limited as long as the substrate includes the above-described base film for a printed circuit board and a metal layer stacked on the base film. Specifically, the metal layer of the substrate for a printed circuit board may not include at least one of the sintered layer, the electroless plating layer, and the electroplating layer. For example, the substrate for a printed circuit board may include the base film for a printed circuit board and a metal sheet that is thermocompression-bonded to the base film. Alternatively, the substrate for a printed circuit board may include the base film for a printed circuit board and metal layers stacked on two surfaces of the base film.

### EXAMPLES

The present invention will now be described in detail by using Examples. The description of Examples does not limit the interpretation of the present invention.

Prototype Nos. 1 to 9 of substrates for printed circuit boards, the substrates including a base film obtained by subjecting a surface of a commercially available polyimide film to an alkali treatment (some of the prototypes were untreated) and a metal layer stacked on the base film, were prepared by the procedure described below. For each of prototype Nos. 1 to 9 of the substrates for printed circuit boards, infrared absorption intensity spectra of a surface of the base film after the alkali treatment and before the stacking of the metal layer and a surface of the base film exposed by removing the metal layer with an acidic solution were measured, and a ratio of the peak intensity around a wave number of 1705 cm⁻¹ to the peak intensity around a wave number of 1494 cm⁻¹ was calculated. Furthermore, a peel strength of the metal layer of each of prototype Nos. 1 to 9 of the substrates for printed circuit boards was measured.

### (Polyimide Film)

In prototype Nos. 1 to 6, a polyimide sheet “APICAL NPI” (average thickness: 25 μm) available from Kaneka Corporation was used as the polyimide film (base film). On the other hand, in prototype Nos. 7 to 9, a polyimide sheet “Kapton ENS” (average thickness: 25 μm) available from Du Pont-Toray Co., Ltd. was used as the polyimide film.

### (Alkali Treatment)

The base films were each immersed for the time shown in Table 1 in an aqueous sodium hydroxide solution at a temperature of 40° C. having a concentration of 9% by mass, the aqueous sodium hydroxide solution serving as an alkali solution.

### (Metal Layer)

The metal layer was formed as follows. First, a copper nano-ink (a metal particle dispersion liquid containing copper particles having a particle size of 80 nm in an amount of 26% by mass) was applied to a surface of the base film and dried. The resulting base film was then fired at 350° C. in a nitrogen atmosphere having an oxygen concentration of 100 ppm by volume for 2 hours to form a sintered layer. Next, copper was stacked by electroless copper plating so as to have an average total thickness of 0.5 μm, and fired at 350° C. in a nitrogen atmosphere having an oxygen concentration of 100 ppm by volume for 2 hours to form an electroless plating layer. Furthermore, copper was stacked by electroplating to stack an electroplating layer. Thus, a metal layer having an average total thickness of 20 μm was formed.

### (Acidic Solution)

The metal layer was removed by immersing each of the prototypes of the substrates for printed circuit boards for 5 minutes in a copper chloride etchant at a temperature of 40° C. having a concentration of 4 mol/L.

### (Total Reflection Infrared Absorption Spectroscopy)

Total reflection infrared absorption spectroscopy was conducted as follows with a total reflection infrared absorption (FT-IR) spectrometer “Nicolet 8700” available from Thermo Fisher Scientific K.K. An absorption intensity spectrum was measured at an angle of incidence of 45° in a measurement wave number range around 4,000 to 650 cm⁻¹ by using a single-reflection ATR accessory “DuraScope” (diamond prism) available from SensiR Technologies LLC in a cumulative number (the number of scans) of 16 in which the resolution in each scan was set to 4 cm⁻¹. From the obtained absorption intensity spectrum, a ratio of the peak intensity around a wave number of 1705 cm⁻¹ to the peak intensity around a wave number of 1494 cm⁻¹ was calculated.

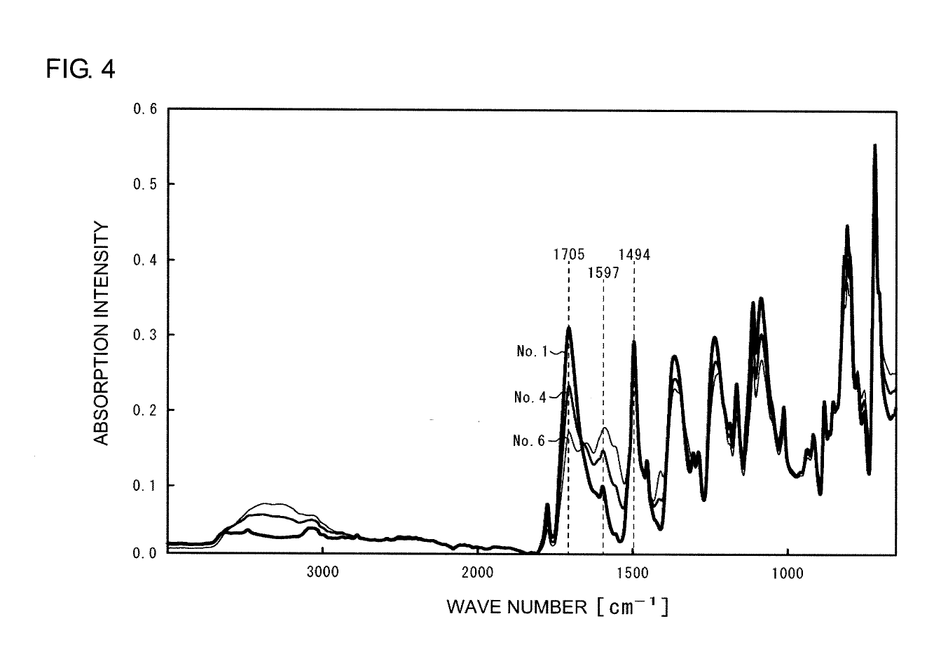

FIG. 4 shows absorption intensity spectra of the surfaces of the base films of prototype Nos. 1, 4, and 6 after the alkali treatment and before the stacking of the metal layer. As shown in the figure, with an increase in the alkali treatment time, the peak intensity around a wave number of 1705 cm⁻¹ decreases and the peak intensity around a wave number of 1597 cm⁻¹ increases, but the peak intensity around a wave number of 1494 cm⁻¹ hardly changes. Although the absolute value may change depending on the measurement apparatus, etc., the peak values can be normalized by calculating the ratio of these peak intensities. Thus, it is believed that the ratio can be used as a control item for ensuring adhesiveness between the base film for a printed circuit board and the metal layer.

### (Peel Strength)

The peel strength of the metal layer was measured by the method according to JIS K6854-2: 1999 “Adhesives-Determination of peel strength of bonded assemblies-Part 2: 180° peel” under the assumption that the base film was regarded as a flexible adherend.

The following Table 1 shows the alkali treatment time, the ratio of the peak intensity around a wave number of 1705 cm⁻¹ to the peak intensity around a wave number of 1494 cm⁻¹ in the absorption intensity spectrum of each of the surface of the base film after the alkali treatment and before the stacking of the metal layer and the surface of the base film after the removal of the metal layer, and the measured value of the peel strength of each of prototype Nos. 1 to 9. Values of the ring-opening ratio of imide rings, the values each being converted from the intensity ratio of the absorption intensity spectrum, are also shown (where the peak intensity ratio of the prototype that was not subjected to the alkali treatment is converted to a ring-opening ratio of 0%, and a peak intensity ratio of zero is converted to a ring-opening ratio of 100%).

TABLE 1

| | | Before stacking of | | After removal of | | |
|---|---|---|---|---|---|---|
| | | metal layer | | metal layer | | |
| | Alkali | Peak | Imide | Peak | Imide | Peel |
| | treatment | intensity | ring-opening | intensity | ring-opening | strength |
| Prototype | time | ratio | ratio | ratio | ratio | [N/cm] |
| No. 1 | Untreated | 1.13 | 0% | 1.12 | 0% | 5.1 |
| No. 2 | 30 seconds | 1.05 | 7% | 1.07 | 5% | 9.8 |
| No. 3 | 90 seconds | 0.90 | 20% | 0.92 | 18% | 10.4 |
| No. 4 | 3 minutes | 0.71 | 37% | 0.75 | 34% | 10.1 |
| No. 5 | 4 minutes | 0.57 | 49% | 0.62 | 45% | 9.7 |
| No. 6 | 5 minutes | 0.41 | 64% | 0.45 | 60% | 5.6 |
| No. 7 | Untreated | 1.12 | 0% | 1.12 | 0% | 4.8 |
| No. 8 | 90 seconds | 1.00 | 11% | 1.03 | 9% | 9.2 |
| No. 9 | 3 minutes | 0.92 | 18% | 0.95 | 16% | 9.9 |

As shown in the table, it was confirmed that the ratio of the peak intensity around a wave number of 1705 cm⁻¹ to the peak intensity around a wave number of 1494 cm⁻¹ did not significantly vary between the measured value of the base film before the stacking of the metal layer and the measured value of the base film after the removal of the metal layer. It is also found that there is a relatively high correlation between the ratio of the peak intensity around a wave number of 1705 cm⁻¹ to the peak intensity around a wave number of 1494 cm⁻¹ in the absorption intensity spectrum and the peel strength, though the relationship between the alkali treatment time and the peel strength significantly varies depending on the type of polyimide film. Specifically, it was confirmed that, in order to achieve a peel strength of 8 N/cm or more, the ratio of the peak intensity around a wave number of 1705 cm⁻¹ to the peak intensity around a wave number of 1494 cm⁻¹ should be 0.50 or more and 1.10 or less.

### REFERENCE SIGNS LIST

1 base film for printed circuit board

2 metal layer

3 sintered layer

4 electroless plating layer

5 electroplating layer

S1 alkali treatment step

S2 measurement step

S3 discrimination step

S4 stacking step

1. A base film for a printed circuit board, the base film comprising a polyimide as a main component,
wherein a ratio of a peak intensity around a wave number of 1705 cm⁻¹ to a peak intensity around a wave number of 1494 cm⁻¹ in an absorption intensity spectrum of a surface of the base film, the spectrum being measured at an angle of incidence of 45° by total reflection infrared absorption spectroscopy, is 0.50 or more and 1.10 or less.

2. A substrate for a printed circuit board, the substrate comprising:
the film for a printed circuit board according to claim 1; and
a metal layer stacked on the surface of the base film for a printed circuit board.

3. The substrate for a printed circuit board according to claim 2, wherein the metal layer includes a sintered layer of metal particles.

4. A method for manufacturing a substrate for a printed circuit board, the substrate including
a base film containing a polyimide as a main component, and
a metal layer stacked on the base film,
the method comprising:
a step of subjecting a surface of the base film to an alkali treatment;
a step of measuring an absorption intensity spectrum of the surface of the base film after the alkali treatment step at an angle of incidence of 45⁰ by total reflection infrared absorption spectroscopy;
a step of discriminating a base film that has, within a predetermined range, a ratio of a peak intensity around a wave number of 1705 cm⁻¹ or a peak intensity around a wave number of 1597 cm⁻¹ to another peak intensity in the absorption intensity spectrum obtained in the measurement step; and
a step of stacking a metal layer on the surface of the base film discriminated in the discrimination step.

5. The method for manufacturing a substrate for a printed circuit board according to claim 4, wherein the discrimination step includes discriminating a base film that has a ratio of the peak intensity around a wave number of 1705 cm⁻¹ to a peak intensity around a wave number of 1494 cm⁻¹ of 0.50 or more and 1.10 or less.

6. The method for manufacturing a substrate for a printed circuit board according to claim 4, wherein the stacking step includes a step of applying a metal particle dispersion liquid to the surface of the base film and heating the metal particle dispersion liquid.
